(19) United States
(12) Patent Application Publication
(10) Pub. No.: US 2009/0229971 A1
(43) Pub. Date: Sep. 17, 2009

(54) Thin-Film Deposition System

(75) Inventor: Masahito Ishihara, Tokyo (JP)

Correspondence Address: HOGAN & HARTSON L.L.P., 1999 AVENUE OF THE STARS, SUITE 1400, LOS ANGELES, CA, 90067, US

(73) Assignee: CANON ANELVA CORPORATION, Tokyo (JP)

(21) Appl. No.: 12/422,056

(22) Filed: Apr. 10, 2009

Related U.S. Application Data
(63) Continuation of application No. 10/925,935, filed on Aug. 26, 2004.

(30) Foreign Application Priority Data
Aug. 28, 2003 (JP) 2003-304725

(51) Int. Cl. C23C 14/34

(52) U.S. Cl. 204/192.13; 204/298.07

(57) ABSTRACT

This application discloses a thin-film deposition apparatus comprising a vacuum chamber and a partition separating the inside of the vacuum chamber into two areas. A substrate is capable of passing through an inside opening provided in the partition. The inside opening is closed by a valve. A thin film is deposited onto the substrate in the first area. The substrate is heated by a heater in the second area prior to the deposition. The substrate is held by a holder in point contact while heated. A boosting-gas is introduced into the second area during the heating, thereby increasing pressure up to a viscous flow range. A pumping line evacuates the first area at a vacuum pressure all the time. The pumping line also evacuates the introduced boosting-gas from the second area to make the second area at a vacuum pressure when the valve is opened.

### BACKGROUND OF THE INVENTION

1. Field of the Invention

This invention relates to a thin-film deposition system such as sputtering system.

2. Description of the Related Art

Deposition of a thin film onto a substrate is widely carried out in manufacturing semiconductor devices and other electronic parts. For example, a conductor film or insulator film is deposited on a substrate for forming a fine circuit thereon in manufacturing a semiconductor device such as memory or processor, an electronic element such as piezoelectric element or sensor head, or a display device such as liquid crystal display or plasma display.

In a thin-film deposition system depositing such a thin film onto a substrate, the substrate is often heated prior to or during the deposition. For example, prior to deposition a substrate is heated for degassing, i.e., release of adsorbed gasses, so that the gasses can not be released thermally from the substrate during the deposition. Heating of a substrate is also carried out during deposition in the case the deposition rate is enhanced when the substrate is at a hot temperature.

As a method of heating a substrate, a heat body with which the substrate is contacted is employed, utilizing heat transmission by the contact conduction. This method often employs a mechanical clamp clamping the substrate to the heat body for enhancing the contact thereof. As well, the method often employs boosting-gas introduction into the interface of the substrate and the heat body for enhancing the heat transmission therebetween. This is in consideration of that minute spaces formed on the interface are at a vacuum pressure. Moreover, the method often employs an electrostatic chuck (ESC) chucking the substrate onto the heat body by the electrostatic force for enhancing the contact thereof.

In the manufacture of semiconductor devices and electronic parts, levels of circuit integration and circuit fineness have been advancing much. In addition, lamination of thinned substrates and light exposure of the both surfaces of a substrate has been carried out widely. In a light-exposure steps, the focus accuracy improvement by reducing scars on the back side of a substrate is demanded more seriously than ever, as well as reduction of the number of particles on the right side of the substrate. In manufacturing a piezoelectric element or relay element, the process accuracy is demanded for the back side of a substrate as well as the right side.

### SUMMARY OF THE INVENTION

This invention is to meet the above-described demands, and presents a thin-film deposition apparatus comprising a vacuum chamber and a partition separating the inside of the vacuum chamber into two areas. A substrate is capable of passing through an inside opening provided in the partition. The inside opening is closed by a valve. A thin film is deposited onto the substrate in the first area by a deposition unit. The substrate is heated by a heater in the second area prior to the deposition. The substrate is held by a holder while heated by the heater. The substrate is in point contact with the holder. A boosting-gas is introduced into the second area during the heating, thereby increasing pressure in the second area up to a viscous flow range. A pumping line evacuates the first area at a vacuum pressure all the time. The pumping line also evacuates the introduced boosting-gas from the second area to make the second area at a vacuum pressure when the valve is opened to make the second area communicate with the first area.

### BRIEF DESCRIPTION OF DRAWINGS

FIG. 1 is a schematic front cross-sectional view of a thin-film deposition system as a preferred embodiment of the invention.

FIG. 2 is a schematic plane view of the heat body 31 shown in FIG. 1.

FIG. 3 is a schematic front cross-sectional view showing operation of the system in FIG. 1.

FIG. 4 is a schematic plane view of a thin-film deposition system of another preferred embodiment.

FIG. 5 is a schematic cross-sectional view on the X-X in FIG. 4

### DETAILED DESCRIPTION OF THE PREFERRED EMBODIMENTS

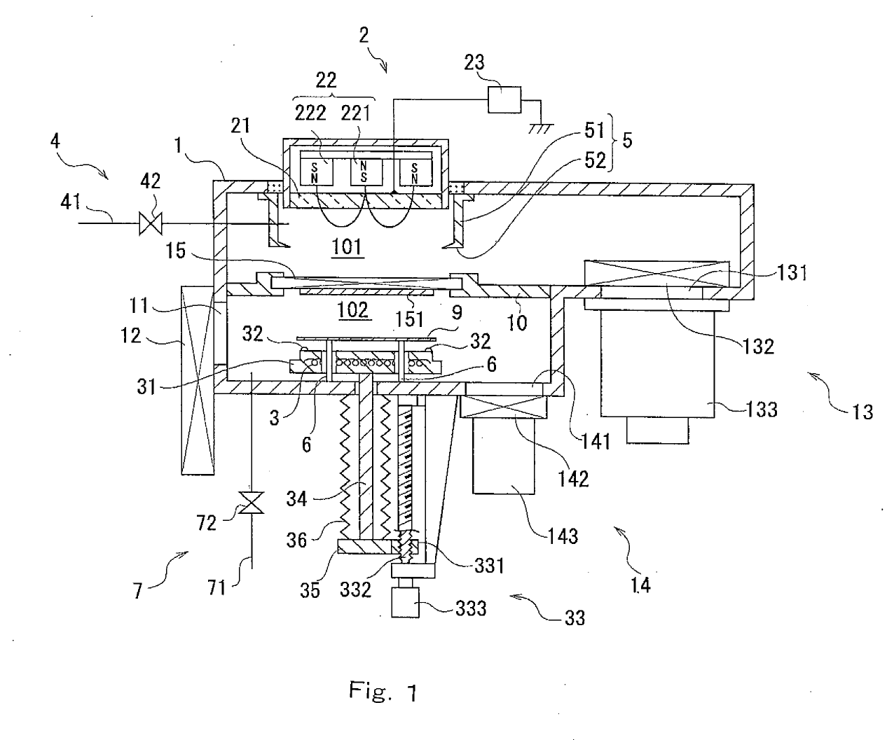

The preferred embodiments of this invention will be described as follows. The system shown in FIG. 1 comprises a vacuum chamber equipped with a couple of pumping lines 13,14, and a deposition unit 2 for a thin-film deposition onto a substrate 9 in the vacuum chamber 1. The system further comprises a heater 3 heating the substrate 9 prior to the deposition, and a holder holding the substrate 9 while heated by the heater 3. The substrate 9 is in the point contact with the holder.

A partition 10 is provided, separating the inside of the vacuum chamber 1 into to two areas, which are the upper area 101 and the lower area 102. The partition 10 comprises an opening through which the substrate 9 is capable of passing, and a valve 15, hereinafter “partition valve”, closing the opening. The opening is hereinafter called “inside opening”.

A reflector 151 is provided on the undersurface of the partition 10. The reflector 151 may be a reflecting plate fixed to the partition 10 or a reflecting film deposited on the partition 10. The reflector 151 reflects radiant rays emitted from the heated substrate 9, returning them to the substrate 9. As a result, efficiency of the heating is enhanced.

The deposition unit 2 is installed in the upper wall of the vacuum chamber 1 so that a thin-film can be deposited onto the substrate placed in the upper area 101. The structure and components of the deposition unit 2 is appropriately designed according to contents of the deposition, e.g., method, kind of the film, and the like. This embodiment employs the deposition unit 2 that carries out sputtering.

Concretely, the deposition unit 2 comprises a target 21 exposed to the upper area 101, a magnet assembly 22 provided behind the target 21, and a sputtering power source 23 to apply voltage for the sputtering to the target 21. The target 21 is made of the same material as the thin film to be deposited. For example, in the case an aluminum film for wiring is deposited, the target 21 is made of aluminum or aluminum alloy. The magnet assembly 22 is to enable the magnetron sputtering. The magnet assembly 22 includes a center magnet 221 and a peripheral magnet 222 surrounding the center magnet 221. A rotation mechanism to rotate the magnet assembly 22 relatively against the target 21 may be provided so that the erosion on the target 21 can be made uniform.

The system comprises a deposition-gas introduction line 4 introducing a gas for the deposition into the upper area 101. The deposition-gas introduction line 4 comprises a pipe 41 communicating with the upper area 101 in the vacuum chamber 1, and a valve 42 and a gas-flow controller (not shown) both provided on the pipe 41. Because of the deposition by the sputtering, a gas for the sputtering discharge such as argon or nitrogen is used as the deposition gas. In the case the system carries out chemical vapor deposition (CVD), a means for introducing a reactive gas is provided as the deposition unit 2.

The system comprises a deposition shield 5 lengthened downward from the upper wall of the vacuum chamber 1. The upper end of the deposition shield 5 surrounds the target 15. The deposition shield 5 is to prevent sputter-particles, which means particles released from the target 21 during the sputtering, from unnecessarily adhering to interior surfaces of the vacuum chamber 1. The deposition shield 5 is essentially composed of a cylindrical portion 51 with a diameter a little wider than the target 21, and an end portion 52 that is a ring-shaped-plate and fixed to the bottom end of the cylindrical portion 51. The cylindrical portion 51 and the end porting 52 both are coaxial to the target 21. The substrate 9 is circular. The inner diameter of the end portion 52 is a little larger than the diameter of the substrate 9.

The heater 3 is installed within a heat body 31. The heat body 31 is commonly used for the holder. The heat body 31 is disposed in the lower area 102 on standby. The heat body 31 is a stage on which the substrate 9 is placed to be heated. The heater 3 is the resistance heating type. The heat body 31 comprises protrusions 32 on the upper surface. The placed substrate 9 is in contact only with the protrusions 32.

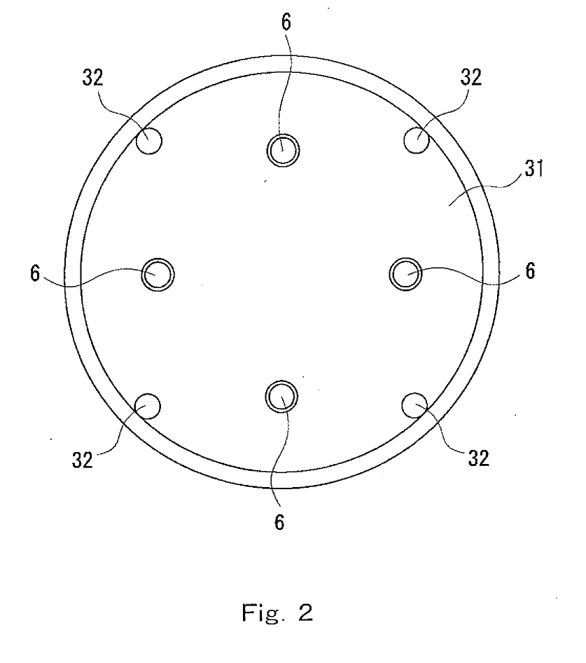

As shown in FIG. 2, the heat body 31 in this embodiment is circular in the plane view, and four protrusions 32 are provided. Each protrusion is located along the edge of the heat body 31 with equal distances, i.e., at every 90 degree. The substrate 9 is held only by the placement onto the heat body 31. That is, this embodiment comprises neither means for electro-statically chucking the substrate 9 nor means for mechanically clamping the substrate 9.

Four through holes are provided with equal distances in the heat body 31. As shown in FIG. 2, a transfer pin 6 is provided in each through hole. Each transfer pin 6 is fixed uprightly on the bottom of the vacuum chamber 1. There may be the case that only three transfer pins 6 are respectively provided in three through holes provided at every 120 degree.

As shown in FIG. 1, the system of this embodiment comprises a locator 33 locating the substrate 9 with an adjusted distance from the heating body 32. In this embodiment, the locator 33 adjusts the distance by shifting the heat body 31. The locator 33 is provided outside the vacuum chamber 1. The heat body 31 is supported by a column 34. An opening through which the column is inserted is provided in the bottom of the vacuum chamber 1. The bottom end of the column 34 is located beneath the vacuum chamber 1, and a bracket 35 is fixed thereto.

The locator 33 comprises a driven screw 331 fixed to the bracket 35, a driving screw 332 engaging the driven screw 331, and a motor 333 rotating the driving screw 332. The driven screw 331 and the driving screw 332 compose a so called precision screw mechanism. The driving screw 332 is vertically lengthened and hung from the bottom of the vacuum chamber 1 by a fixing member 334. The driving screw 332 is capable of rotation around the vertical axis and not capable of elevation. The motor 333, specifically a servo motor, rotates the driving screw 332, thereby shifting up and down the bracket 35, the column 34 and the heat body 31 together. A bellows 36 is provided, surrounding the column 34. The top end of the bellows 36 is air-tightly fixed to the bottom of the vacuum chamber 1, surrounding the opening through which the column 34 is inserted. The bottom end of the bellows 36 is air-tightly fixed to the bracket 35. The bellows 36 prevents leakage of vacuum through the opening through which the column 34 is inserted. The system comprises a carrier carrying the heated substrate 9 to a position in the upper area 101, at which the substrate 9 has to be located during the thin-film deposition, hereinafter “deposition position”. The described locater 33 is commonly as the carrier The locater 33 carries the substrate 9 to the deposition position through the inside opening.

The system further comprises a boosting-gas introduction line 7 introducing a gas into the lower area 102 so that pressure can be increased to be in a viscous flow range. The boosting-gas introduction line 7 comprises a pipe 71 communicating with the lower area 102 in the vacuum chamber 1, and a valve 72 and a gas-flow controller (not shown) both provided on the pipe 71. The boosting gas is introduced for enhancing efficiency of the heating. Therefore, such a gas as helium, argon or nitrogen having high coefficient of thermal conductivity is used as the boosting gas.

An opening 11 for transferring the substrate 9, hereinafter “transfer opening”, is provided in the side wall of the vacuum chamber 1. The transfer opening 11 is closed by a valve 12, hereinafter “transfer valve”. The transfer opening 11 and the transfer valve 12 are located as high as the lower area 102.

The vacuum chamber 1 is equipped with a couple of pumping lines 13,14. The first pumping line 13 is to evacuate the upper area 101 solely. The second pumping line 14 is to evacuate the lower area 102 solely.

As shown in FIG. 1, the vacuum chamber 1 has the cross-sectional configuration that the upper area 101 is wider than the lower area 102, jutting to the side. The first pumping line 13 evacuates the upper area 101 through an evacuation hole 131 provided at the jutting portion of the vacuum chamber 1. The first pumping line 13 comprises a main valve 142 adjacent to the evacuation hole 131, a vacuum pump 143 evacuating the upper area 101 through the main valve 142, and a pumping speed controller (not shown).

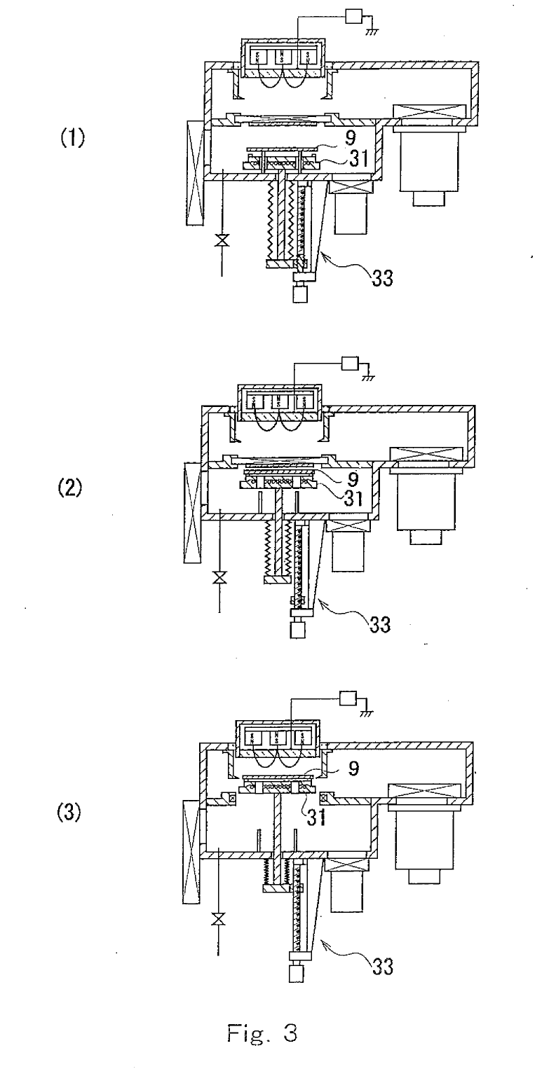

Operation of the system of this embodiment is described as follows, referring to FIG. 3. Though the system can be a cluster-tool type, the following description is on the assumption that it is a stand-alone type.

The upper area 101 is evacuated to be at a required vacuum pressure by the first pumping line 13 in advance. The lower area 102 is made at atmospheric pressure by the boosting-gas introduction line 7 or a ventilation-gas introduction line (not shown). The heat body 31 is located at a standby position in the lower area 102.

In this state, the transfer valve 12 is opened. Then, the substrate 9 is transferred into the lower area 102 through the transfer opening 11. As shown in FIGS. 3(1), the substrate 9 is plated on the transfer pins 6. This transfer operation is typically carried out by such an automatic mechanism as robot. Still, manual handling by an operator is not excluded in this invention.

After the transfer valve 12 is closed, the second pumping line 14 evacuates the lower area 102 to a required vacuum pressure. Next, the boosting-gas introduction line 7 is operated to increase pressure in the lower area 102 to the viscous flow range. Then, as shown in FIGS. 3(2), the locator 33 shifts the heat body 31 up to a required upper position. In this elevation, the substrate 9 is passed from the transfer pins 6 to the heat body 31, being placed thereon. The substrate 9 is in contact with the protrusions 32 only.

The heat body 31 is in a state of hot temperature because the heater 3 is operated in advance. Therefore, the placed substrate 9 is heated by the heat body 31. In this heating, the conductive heat transmission is minor because the contact area of the substrate 9 onto the heat body 31 is small, and the heat transmission via the gas molecules in the space, which includes convection, is major. In addition, the substrate 9 is heated by radiant rays from the heat body 31

After the substrate 9 is heated up to a required temperature, the boosting-gas introduction line 7 stops the operation, and the second pumping line 14 evacuates the lower area 102 again down to a required vacuum pressure. Then, the partition valve 15 is opened, and the locator 33 shifts the heat body 31 up further. When the substrate 9 reaches the deposition position, the locator 33 stops shifting. As shown in FIGS. 3(3), the deposition position is where the substrate 9 is inside the end portion 52.

After the substrate 9 is located at the deposition position, the deposition-gas introduction line 4 is operated to introduce the deposition gas at a required flow rate confirming by a vacuum gauge (not shown) that the vacuum chamber 1 is kept at a required vacuum pressure, the sputtering power source 23 is operated to apply the voltage to the target 21, thereby igniting the sputter discharge. As a result, sputter-particles released from the target 21, which are normally in a state of atom, reach the substrate 9, depositing a thin film. In this sputtering, because the heater 3 keeps the operation, the substrate 9 is continuously heated by the heater 3. Still, the heating efficiency might decrease compared to the one during the heating, when pressure in the upper area 101 under the introduction of the deposition gas is lower than under the introduction of the boosting gas.

After the deposition is carried out for a required thickness of the film, the sputtering power source 23 is stopped, and the vacuum chamber 1 is evacuated again at a required vacuum pressure by the first and second pumping lines 13,14. Afterward, the locator 33 shifts the heat body 31 down to the initial standby position. In this shift down, the substrate 9 is passed to the transfer pins 6 and placed thereon.

After the partition valve 15 is closed, the lower area 102 is ventilated to be at atmospheric pressure by the boosting-gas introduction line 7 or the ventilation gas introduction line (not shown). Then, the transfer valve 12 is opened, and the substrate 9 is transferred to the outside through the transfer opening 11.

During heating the substrate 9, the locator 33 locates the substrate 9 with an appropriately-adjusted distance from the surface of the heat body 31. The above-described operation is the example where the distance is adjusted to zero, that is, the substrate 9 is contacted onto the heat body 31. The locator 33 may dispose the heat body 31 at a lower position, making the substrate 9 placed on the transfer pins 6. In this state, the substrate 9 is floated, i.e., apart from the heat body 31. The distance is adjusted by the shift-down length of the heat body 31, thereby adjusting the total efficiency of the heating.

In the above-described system, the heating can be highly efficient even through the point contact of the substrate 9 onto the heat body 31, because pressure in the lower area 102 is made in the viscous flow range by the boosting gas introduction. The point that the substrate 9 is held only through the point contact brings the advantage of reducing the probability of the scar generation on the back surface of the substrate 9. During the heating, the substrate 9 and the heat body 31 thermally expand. The back surface of the substrate 9 is slightly rubbed with the heat body 31. If the contact area of the substrate 9 onto the heat body 31 is larger, the probability of the scar generation is higher. As in this embodiment, contrarily, if the substrate 9 is held only through the point contact, the probability of the scar generation is very low.

Because the point contact is for inhibiting the scar generation, “how much small the contact area is”, satisfying the term “point contact”, corresponds to “as far as the scar generation is sufficiently inhibited”. Specifically, the contact area of one point, i.e., one protrusion, is preferably in the range of 0.15 mm² to 100 mm², more preferably 0.2 mm² to 7 mm². If the contact area is larger than 100 mm², the scar generation is not inhibited sufficiently. If the contact area of one point is smaller than 0.15 mm², the substrate 9 is in a state of being placed on a sharp protrusion like the tip of a needle. Therefore, the scar generation would be rather promoted. The protrusion with the contact area of 0.15 mm² to 100 mm² does not bring these problems, and the contact area of 0.2 mm² to 7 mm² is completely free from these problems.

The protrusions 32 shown in FIG. 2 are hemisphere shaped. This is one example for the point contact. Still, any protrusions having square contact areas or ellipse cross sections may be employed. The heat dissipation is a little in the structure that the substrate 9 is held through the point contact. This also contributes to enhancing the heating efficiency.

As described, the substrate 9 is held, only being placed on the protrusions 32. That is, the substrate 9 is neither electro-statically chucked nor mechanically clamped onto the heat body 32, but just placed thereon. This point also contributes to reduction of the scar generation on the back side of the substrate 9. The electro-static chuck and the mechanical clamp are effective to enhancing the conductive heat transmission. However, scars are easily generated because the substrate 9 is strongly pressed onto the heat body 31. This embodiment accomplishes the high heating efficiency neither by electro-statically chucking nor by mechanically clamping, but by increasing pressure of the atmosphere, that is, by enhancing the heat transmission via the gas molecules. Therefore, the scar generation on the back surface of the substrate 9 is inhibited furthermore. As understood from the above description, “the substrate is held through only the placement on the protrusions” means that it is pressed to the protrusions only by its own weight without any electrostatic chucking force and without any mechanical clamping force. Strictly, the frictional force acts at the interface between the substrate 9 and the protrusions 32, and the gas molecules in the space press the substrate 9. “The substrate is held through only the placement on the protrusions” does not exclude the actions of these forces.

The heat body 31 has the technical meaning of enlarging the contact area with the introduced boosting gas. In the case where the heater 3 itself has a large surface area, the heat body 31 is dispensable. The substrate 9 needs to hold a position in the vacuum chamber 1 during the heating. In this embodiment, the heat body 31 is commonly used as the holder for making the substrate 9 hold the position. Therefore, the structure in the vacuum chamber 1 is simplified, and the number of the components is reduced, cutting down the system cost thereby.

As described, the inside of the vacuum chamber 1 is separated into two areas 101,102 by the partition 15, and the deposition is carried out in the upper area 101 separated from the lower area 102 where pressure is in the viscous flow range. This point brings the advantage of preventing the boosting gas from affecting the property of the thin-film deposition. Without the partition 10, that is, in a structure the lower area 102 communicates with the upper area 101, the boosting-gas introduced in the lower area 102 diffuses to the upper area 101, resulting in that such contamination as incorporation of the gas molecules into the deposited film would take place. This embodiment with the partition 10 is free from this problem. As described, the locator 33 locates the substrate 9 with the adjusted distance from the surface of the heat body 31. This adjustment enables fine control of the heating, enhancing accuracy of the heating.

The shift of the heat body 31 against the standing transfer pins 6 is for transferring the substrate 9 between the heat body 31 and the transfer pins 6. The locator 33 shifting the heat body 31 is commonly used as the means for transferring. This point also brings the advantages of simplifying the chamber structure and reducing the system cost by cutting down the number of the components. For transferring the substrate 9 between the heat body 31 and the transfer pins 6, the locator 33 may shift all of the transfer pins 6 together, making the heat body 31 standing.

The advantages of simplifying the chamber structure and reducing the system cost by cutting down the number of the components are further brought by the structure that the locator 33 is capable of shifting the substrate 9 to the upper area 101 and placing it at the deposition position. If not the locator 33 is as such, additionally the carrier is required for carrying the heated substrate 9 to the deposition position.

The system may be designed so as to cool the substrate 9 in the lower area 102 after the deposition. For example, the flow of a coolant gas is made in the lower area 102 when the processed substrate 9 is passed from the heat body 31 to the transfer pins 6. The coolant gas cooled at a required cold temperature flows along the substrate 9, thereby cooling it.

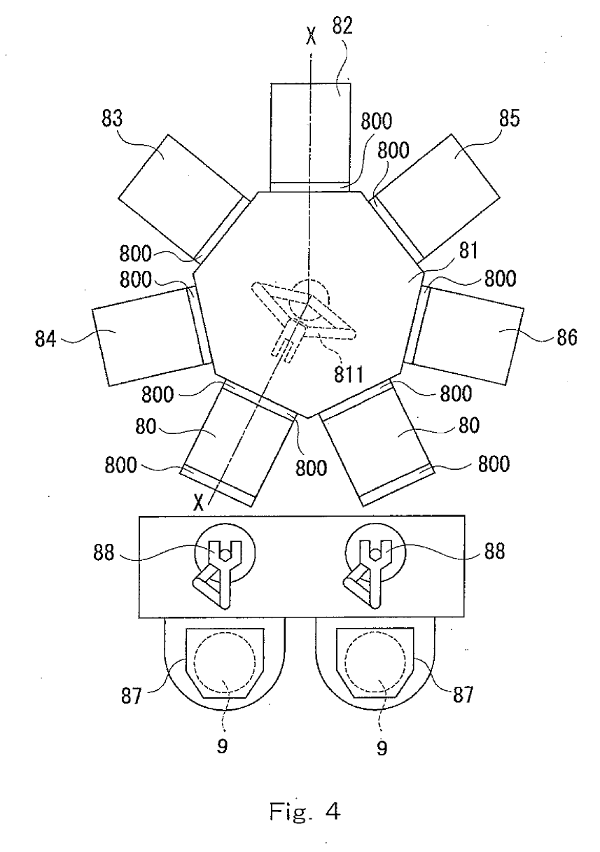

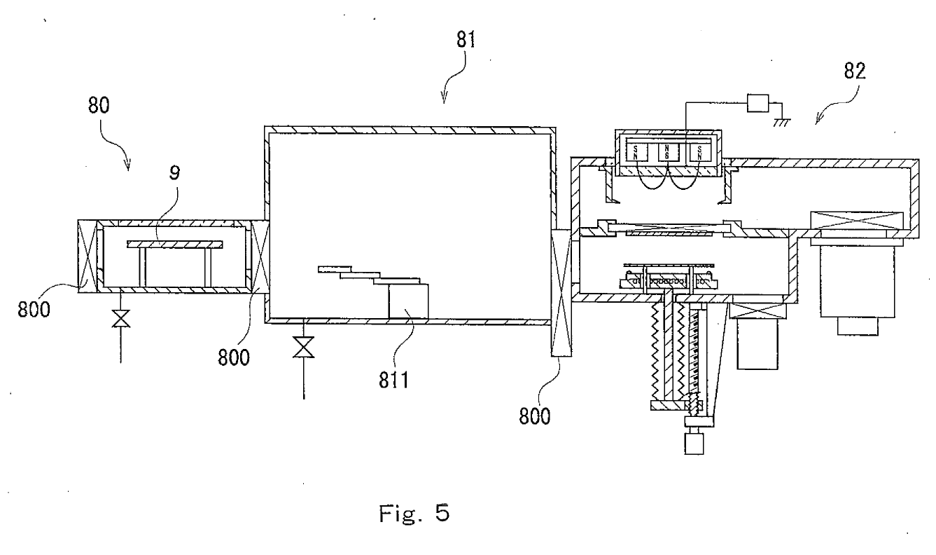

Next, the thin-film deposition system as the other embodiment of the invention, which is shown in FIG. 4 and FIG. 5, will be described as follows. The system shown in FIG. 4 and FIG. 5 is one of the cluster tool type. Concretely, as shown in FIG. 4, a transfer chamber 81 is provided center, and process chambers 82 to 86 and a load-lock chambers 80 are connected air-tightly on the periphery of the transfer chamber 81. A transfer valve 800 is provided at each boundary of each chamber 80, 82 to 86. A thin-film deposition process is carried out in the process chamber 82. The structure of the process chamber 82 may be the same as of the vacuum chamber 1 in the described embodiment. Therefore, detailed description is omitted.

A transfer robot 811 is provided in the transfer chamber 81. The transfer robot 811 comprises a multi-joint type arm. The substrate 9 is held at the tip of the arm while transferred. The transfer robot 811 is preferably the one optimized for usage in vacuum environment, for example, without releasing dusts. Structures in the process chambers 83 to 86 are optimized according to the processes carried out therein. In the case a multilayer film is deposited, for example, the chambers 83 to 86 may be designed so as to carry out thin film depositions therein as well. One of the chambers 83 to 86 may be for cooling the substrate 9 after the deposition(s). As shown in FIG. 4, cassettes 88 in which unprocessed or processed substrates 9 are stored are provided at the atmospheric outside. Auto loaders 87 are provided for transferring the substrates 9 between the cassettes 87 and the load-lock chambers 80.

In this system, any of the substrates 9 is transferred by any of the auto loaders 88 from any of the cassettes 87 to any of the load-lock chambers 80. After the load-lock chamber 80 is evacuated at the same vacuum pressure as in the transfer chamber 81, the transfer valve 800 is opened, and the substrate 9 is transferred from the load-lock chamber 80 to the process chamber 82 by the transfer robot 811.

In this, the lower area in the process chamber 82 is evacuated at the same vacuum pressure as in the transfer chamber 81 by the second pumping line in advance. After the transfer valve 800 is closed, the pre-heating and the deposition onto the substrate 9 are carried out through the same operation as described. After the process in the process chamber 82 is finished, the substrate 9 is transferred out thereof. In this, the lower area is evacuated again at the same vacuum pressure as in the transfer chamber 81 by the second pumping line, not ventilating to atmospheric pressure. Afterward, the substrate 9 is transferred to the process chambers 83 to 86 in order, and the required processes are carried out in the process chamber 83 to 86 in order. After all the processes are finished, the substrate 9 is transferred to any of the load-lock chambers 80. Then, the substrate 9 is returned to any of the cassettes 87 and stored therein by any of the auto loaders 88.

In this embodiment, the lower area of the process chamber 82 is at a vacuum pressure even when the substrate 9 is transferred in and out. Therefore, the heat body disposed in the lower area of the process chamber 82 is under a vacuum pressure all the time, being not exposed to the atmosphere. In other words, the load-lock chamber 80 isolates the second area from the outside atmosphere. If the heat body in the state of a hot temperature is exposed to the atmosphere, the surface would be oxidized by oxygen or moisture in the atmosphere. The oxidized surface could be the source of contaminants, releasing oxide contaminants. The system of this embodiment is free from this problem because the heat body is under the vacuum pressure all the time. The phrase “all the time” in this description means “all the time while the system is regularly operated”. When operation of the system is suspended for maintenance, for example, the lower area is ventilated to be at atmospheric pressure, not at a vacuum pressure. In this situation, the heat body may be exposed to the atmosphere, because it is not at a hot temperature but at room temperature.

As a system comprising a load-lock chamber, i.e., other than the stand-alone type, an inline type is practical as well as the described cluster-tool type. The system of the invention can be modified to the inline type. An inline type system has a structure where a multiplicity of chambers are provided serially in a line. In any type other than the stand-alone type, though the load-lock chamber 80 is required between the process chamber 82 and the outside atmosphere, the process chamber 82 may communicate directly with the load-lock chamber 80 without another chamber such as the transfer chamber 81. In other words, the load-lock chamber 80 may communicate either directly or indirectly with the process chamber 82, as far as the vacuum environment is continuously maintained.

In the above-described embodiment, the first area was at the upper side, and the second area 102 was at the lower side. This may be inverted. Otherwise, the first and the second areas may be disposed side by side. This structure is practical in the case where the substrate posing upright is transferred into the chamber. Though the vacuum chamber 1 in the described embodiment was equipped with the couple of the pumping lines 13,14, only one pumping line may be provided and commonly used. In this case, the first and the second areas are evacuated at optimum timing by the open-close operations of valves provided on evacuation pipes. One vacuum pump may be commonly used as a roughing pump in the other pumping line.

1-10. (canceled)

11. A sputtering system, comprising:
a vacuum chamber;
a partition separating an inside of the vacuum chamber into two areas of first and second;
an inside opening provided in the partition;
a partition valve capable of gas-tightly closing the inside opening;
a holder for holding the substrate in the first and second areas;
protrusions provided on an upper surface of the holder and having tops to which the held substrate is contacted apart form a rest of the upper surface of the holder;
a deposition unit for depositing a thin film by sputtering onto the substrate held by the holder in the first area;
a heater for heating the substrate held by the holder in the second area;
a boosting-gas introduction line connected to the second area for introducing a boosting gas into the second area when the partition valve gas-tightly closes the inside opening;
a gas flow controller for controlling a flow of the boosting gas introduced by the boosting-gas introduction line so that a pressure in the second area is in a viscous flow range;
a first pumping line connected to the first area and capable of evacuating the first area at a vacuum pressure;
a second pumping line connected to the second area and capable of evacuating the introduced boosting gas from the second area to make pressure of the second area at a vacuum pressure before the partition valve is opened; and
a carrier for carrying the holder with the heated substrate held to a required position in the first area through the inside opening when the partition valve is opened after the substrate is heated up to a required temperature by the heater, wherein
the inside opening has a size where the holder with the substrate held is capable of passing through, and
the holder is provided separately from the partition valve and comprises no member engaging the partition.

12. A sputtering system as claimed in claim 11, further comprising a reflector on an undersurface of the partition valve, the reflector being provided at a position of facing the substrate in the second area when the partition valve is closed.

13. An electronic device manufacturing system, comprising:
a vacuum chamber;
a partition separating the inside of the vacuum chamber into two areas of first and second;
an inside opening provided in the partition;
a partition valve capable of gas-tightly closing the inside opening;
a holder for holding the substrate in the first and second areas;
protrusions provided on an upper surface of the holder and having tops to which the held substrate is contacted apart form a rest of the upper surface of the holder;
a deposition unit for depositing a thin film onto the substrate held by the holder in the first area;
a heater for heating the substrate held by the holder in the second area;
a boosting-gas introduction line connected to the second area for introducing a boosting gas into the second area when the partition valve gas-tightly closes the inside opening;
a gas flow controller for controlling a flow of the boosting gas introduced by the boosting-gas introduction line so that a pressure in the second area is in a viscous flow range;
a first pumping line connected to the first area and capable of evacuating the first area at a vacuum pressure;
a second pumping line connected to the second area and capable of evacuating the introduced boosting gas from the second area to make pressure of the second area at a vacuum pressure before the partition valve is opened; and
a carrier for carrying the holder with the heated substrate held to a required position in the first area through the inside opening when the partition valve is opened after the substrate is heated up to a required temperature by the heater, wherein
the inside opening has a size where the holder with the substrate held is capable of passing through, and
the holder is provided separately from the partition valve and comprises no member engaging the partition.

14. An electronic device manufacturing system as claimed in claim 13, further comprising a reflector on an undersurface of the partition valve, the reflector being provided at a position of facing the substrate in the second area when the partition valve is closed.

15. A method for manufacturing an electronic device, comprising:
separating an inside of a vacuum chamber into two areas of first and second by a partition;
placing a substrate on tops of protrusion provided on an upper surface of a holder, thereby making the holder hold the substrate;
evacuating the first area at a vacuum pressure by a first pumping line;
heating the substrate by a heater in the second area as the substrate is held by the holder;
introducing a boosting gas into the second area while the substrate is heated by the heater;
controlling a flow rate of the boosting gas so that pressure in the second area is in the viscous flow range while the substrate is heated by the heater;
closing an inside opening in the partition by a partition valve during introducing the boosting gas;
evacuating the introduced boosting gas from the second area by a second pumping line to make the second area at a vacuum pressure after the substrate is heated up to a required temperature by the heater;
opening the partition valve after evacuating the second area at the vacuum pressure by the second pumping line;
carrying the holder with the substrate held through the inside opening to a required position in the first area after the partition valve is opened; and
depositing a thin film on the substrate held by the holder at the required position in the first area.

16. A method for manufacturing an electronic device as claimed in claim 15, further comprising:
providing a reflector on an undersurface of the partition valve; and
making radiation from the substrate reflect on the reflector back to the substrate when the partition valve closes the inside opening
